(19) United States
(12) Patent Application Publication
(10) Pub. No.: US 2026/0039286 A1
(43) Pub. Date: Feb. 5, 2026

(54) COMPARATOR WITH HYSTERESIS AND ELECTRONIC DEVICE

(71) Applicant: ams-OSRAM AG, Premstaetten (AT)

(72) Inventor: Emir SERDAREVIC, Feldkirchen bei Graz (AT)

(21) Appl. No.: 18/995,189

(22) PCT Filed: Jul. 26, 2023
(86) PCT No.: PCT/EP2023/070721

§ 371 Date: Jan. 16, 2025

(30) Foreign Application Priority Data
Jul. 29, 2022 (DE) 10 2022 119 099.4

(51) Int. Cl. H03K 5/24

(52) U.S. Cl. CPC H03K 5/2481

(57) ABSTRACT

A comparator includes an input stage configured to receive a pair of input signals to generate at least one differential current signal. The comparator further includes an output stage configured to generate an output signal depending on the differential current signal. The output stage includes a current mirror and a node electrically connected to the current mirror. The current mirror includes a first transistor, a second and a third transistor, the second and the third transistors being connected in parallel. The comparator further comprises a gain stage including a first and a second inverter, wherein an output of the first inverter is input to the second inverter. An output of the second inverter is configured to control the third transistor to be in a floating or conducting state.

### CROSS-REFERENCE TO RELATED APPLICATIONS

This application is a US National Stage application, filed under 35 U.S.C. § 371, of International Application PCT/EP2023/070721, filed on Jul. 26, 2023, and claims priority to German application 10 2022 119 099.4, filed on Jul. 29, 2022, the entirety of the above listed applications is incorporated herein by reference.

A Comparator is usually applied to differentiate between two different signal levels. Thereby, two voltages or currents are compared and a digital signal indicating which one is larger is output. Comparators are frequently used components or circuit elements, e.g., for analog-to-digital converters (ADCs), two-point or three-point controllers, or switching power supplies.

In greater detail, common comparator circuits comprise two analog input terminals for receiving input signals e.g., V₋, V₊, and one binary digital output terminal for outputting an digital output signal e.g., Vₒᵤₜ. If V₊ is larger than V₋, then Vₒᵤₜ is 1 (logic high). If V₊ is smaller than V₋, then Vₒᵤₜ is 0 (logic low). However, one drawback of such a configuration is that small voltage fluctuations due to noise, which are always present on the input signals V₊, V₋, may cause undesirable rapid changes between the two output states Vₒᵤₜ.

To prevent this output oscillation, a small hysteresis of a few millivolts is integrated into many common comparator circuits. For example, such a comparator may be operated by applying a positive feedback to the comparator. The potential difference between the high and low output signals Vₒᵤₜ and a feedback resistor may be adjusted to change the voltage that is taken as a comparison reference to the input signal V₋.

For example, hysteresis may be using two different threshold voltages, e.g., V_{thL}, V_{thH}, to avoid multiple transitions. In one exemplary configuration, the input signal V₋ may exceed an upper threshold V_{thH} for Vₒᵤₜ to transition to low or below a lower threshold V_{thL} for Vₒᵤₜ to transition to high. Since a margin is provided between the High-to-Low V_{thH} and Low-to-High thresholds, Vₒᵤₜ is not affected (i.e., no chattering occurs) even when the input signal V₋ has a voltage near the threshold voltages V_{thL}, V_{thH}.

However, for applications requiring fast signals an adaption is needed to provide sufficient robustness against noise in the input signals.

### SUMMARY

According to embodiments, a comparator comprises an input stage, configured to receive a pair of input signals to generate at least one differential current signal, an output stage configured to generate an output signal depending on the differential current signal, the output stage comprising a current mirror and a node electrically connected to the current mirror, the current mirror comprising a first transistor, a second and a third transistor, the second and the third transistors being connected in parallel, a gain stage comprising a first and a second inverter, wherein an output of the first inverter is input to the second inverter. In greater detail, an output of the second inverter is configured to control the third transistor to be in a floating or conducting state.

In other words, the third transistor serves as a switch that is switched on and off depending on the output of second converter. This switching configuration implements hysteresis by adapting the current mirror load.

For example, if the output of the second inverter is high, the third transistor may be controlled to be conductive. In this case, a higher current may flow through the output stage raising an upper threshold voltage.

On the other hand, if the output of the second inverter is low, the third transistor may be controlled to be floating. In this case, a smaller current may flow through the output stage reducing a lower threshold voltage.

By the above, hysteresis may be implemented. This configuration may allow adapting the speed of the switching phases such that the comparator may be used for fast signals.

The input stage may comprise a first input transistor and a second input transistor, the first input transistor being different from the second input transistor. In other words, in one configuration of the comparator it may be possible to realize an unsymmetrical input transistor pair. For example, the second input transistor may be smaller than the first input transistor and may be connected to a switching input. The first transistor may be connected to reference. This may allow a faster switching and may provide more headroom for a current source (such as a bias transistor) resulting in a constant and stable current source in saturation.

The comparator may further comprise an inverter and a control transistor. The output of the second inverter may be fed to a gate terminal of the control transistor via the inverter. The control transistor may, depending on the output of the second inverter, control switching the third transistor on or off.

The control transistor may be implemented as an NMOS transistor.

### BRIEF DESCRIPTION OF THE DRAWINGS

The accompanying drawings are included to provide a furthe understanding of embodiments of the present disclosure and are incorporated in and constitute a part of this specification. The drawings illustrate the embodiments of the present disclosure and together with the description serve to explain the principles. Other embodiments of the present disclosure and many of the intended advantages will be readily appreciated, as they become better understood by reference to the following detailed description. The elements of the drawings are not necessarily to scale relative to each other. Like reference numbers designate corresponding similar parts.

FIG. 1 is a schematic diagram illustrating components of a comparator according to embodiments.

FIG. 2 shows an example of input and output signals of a comparator according to embodiments.

FIG. 3 shows an example of an electronic device according to embodiments.

### DETAILED DESCRIPTION

In the following detailed description reference is made to the accompanying drawings, which form a part hereof and in which are illustrated by way of illustration specific embodiments in which embodiments of the present disclosure may be practiced. In this regard, directional terminology such as “top”, “bottom”, “front”, “back”, “over”, “on”, “above”, “leading”, “trailing” etc. is used with reference to the orientation of the Figures being described. Since components of embodiments of the present disclosure can be positioned in a number of different orientations, the directional terminology is used for purposes of illustration and is in no way limiting. It is to be understood that other embodiments may be utilized and structural or logical changes may be made without departing from the scope defined by the claims.

The description of the embodiments is not limiting. In particular, elements of the embodiments described hereinafter may be combined with elements of different embodiments.

As employed in this specification, the terms “coupled” and/or “electrically coupled” are not meant to mean that the elements must be directly coupled together-intervening elements may be provided between the “coupled” or “electrically coupled” elements. The term “electrically connected” intends to describe a low-ohmic electric connection between the elements electrically connected together.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

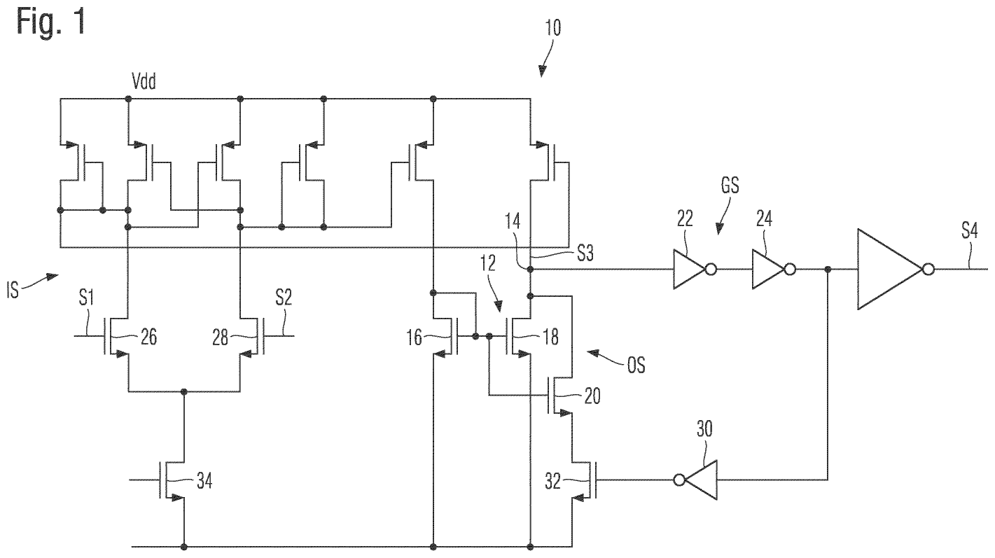

FIG. 1 is a schematic diagram illustrating components of a comparator 10 according to embodiments. The comparator 10 comprises an input stage IS, an output stage OS, and a gain stage GS, as indicated by corresponding arrows in FIG. 1.

The input stage IS may include a bias transistor 34 and input transistors 26, 28. The bias transistor 34 may be configured to operate as a tail current source for a differential input circuit formed by the input transistors 26, 28. A gate terminal of the bias transistor 34 may receive a bias voltage. A source terminal of the bias transistor 34 may be electrically connected to a reference potential, typically Vss or GND.

A gate terminal of the input transistor 26 may form the noninverting input of the comparator 10 and a gate terminal of transistor 28 may form the inverting input of the comparator circuit 10.

The input stage IS may further include a load circuit formed by a plurality of transistors as shown in the upper part of FIG. 1. In this circuit, a pair of cross-coupled transistors may be coupled between the differential input circuit and a positive supply node Vdd. In this context, various configurations are possible. The load circuit shown in FIG. 1 is only by way of example, and there may be many alternative implementations and modifications.

The input stage IS receives a pair of input signals S1, $2 via the input transistors 26, 28, which will be described in detail later on. The input stage IS then generates a differential current signal S3 that is passed to the output stage OS.

The output stage OS generates an output signal S4 depending on the differential current signal S3. The output stage OS comprises a current mirror 12 and a node 14 electrically connected to the current mirror 12. In greater detail, the current mirror 12 may comprise a first transistor 16, a second and a third transistor 18, 20. The second and the third transistors 18, 20 are connected in parallel as shown in FIG. 1.

Furthermore, the gain stage GS comprises a first and a second inverter 22, 24, wherein an output of the first inverter 22 is input to the second inverter 24. The gain stage GS may comprise further inverters as shown in FIG. 1. An output of the second converter 24 is then fed back to the current mirror 12.

In detail, the output of the second inverter 24 controls the third transistor 20 to be in a floating or conducting state.

That is, the third transistor 20 is operated as a switch that is turned on and off depending on the output of the second inverter 24. With this configuration hysteresis is implemented.

For example, if the output of the second inverter 24 is high, the third transistor 20 may be controlled to be conductive or turned on. In this first phase, a higher current may pass or flow through the output stage OS. The current mirror 12 may then have a factor of 2 that may be switched on in the output stage OS.

If the output of the second inverter 24 is low, the third transistor 20 may be controlled to be floating or turned off. In this second phase, a smaller current may pass or flow through the output stage OS. The current mirror 12 may then have a factor of 1 that may be switched on in the output stage OS.

Stated differently, during the first phase the current mirror 12 of factor 2 is switched on, while in the second phase the current mirror 12 of factor 1 is switched on. Via this switching hysteresis is achieved. In one example, the circuit may have an offset value of about 22 mV.

This configuration may make the comparator 10 robust against noise and unwanted switching. In addition, the above configuration may enable to increase the switching speed between the first and the second phase.

Furthermore, according to embodiments the input stage IS may comprise the first input transistor 26 and the second input transistor 28 as described above. The first input transistor 26 may be different from the second input transistor 28. For example, the term “the first input transistor may be different from the second input transistor” may mean that a channel width of the first input transistor 26 is different, e.g. larger than the channel width of the second input transistor. The conductivity type of the first input transistor 26 may be equal to the conductivity type of the second input transistor 28, e.g. NMOS.

For example, the second input transistor 28 may be smaller than the first transistor 26. The second input transistor 28 may be connected to the switching input. This may increase the switching speed. The first transistor 26 may be connected to reference, because the threshold voltage may be smaller, and thus, more headroom for the bias transistor 34 may be available. This may allow a constant and stable current source in saturation. Both effects may enable a fast switching.

The comparator 10 may comprise a control inverter 30 and a control transistor 32 as shown in FIG. 1. These elements may be included in the output stage OS. The output of the second inverter 24 may be fed to a gate terminal of the control transistor 32 via the control inverter 30. The control transistor 32 may control the switching of the third transistor 30 depending on the output of the second converter 24.

The control transistor 32 may be implemented as an NMOS transistor. A source terminal of the control transistor 32 may be connected to Vss, e.g. GND.

Further, also the bias transistor 34, the first and second input transistors 26, 28, the first, second, and third transistors 16, 18, 20 as well as the control transistor 32 may be implemented as NMOS transistors. According to further examples, the transistors may be implemented as PMOS transistors.

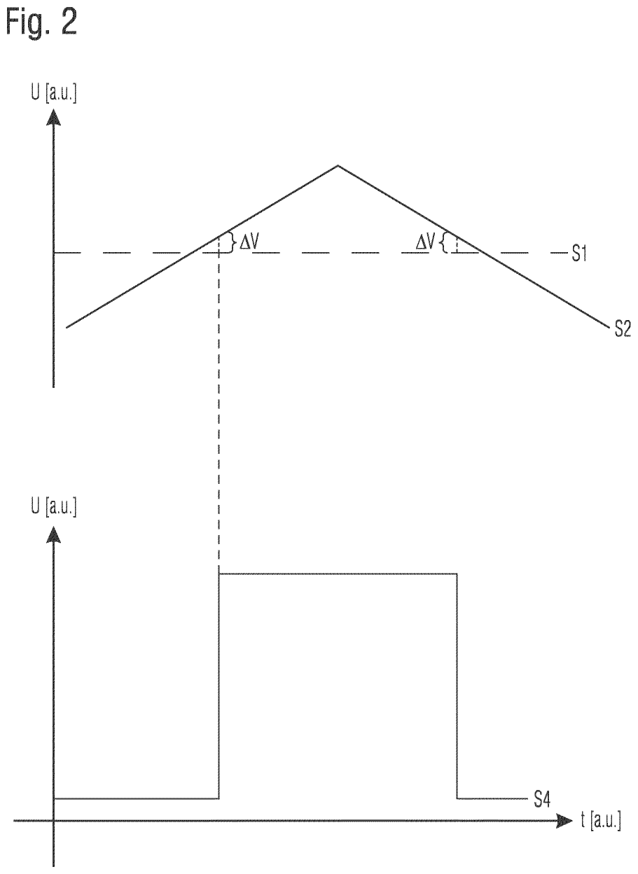

FIG. 2 illustrates an example of voltage characteristics of the comparator. FIG. 2 shows a reference signal S1, a switching input signal S2 and the output signal S4. Approximately at a timing, at which S2 crosses S1, the output S4 is switched from HIGH to LOW or vice versa. Due to the specific configuration discussed herein, a hysteresis is imposed which means that switching to HIGH is performed with a delay after S2 is larger than S1. On the other side, S4 is switched to LOW before S2 is smaller than S1. The voltage difference between S2 and S1 which causes the switching is referred to as the offset voltage ΔV. For example, ΔV may be smaller than 50 mV and larger than 5 mV. For example, ΔV may be approximately 15 to 25 mV, e.g. 22 mV.

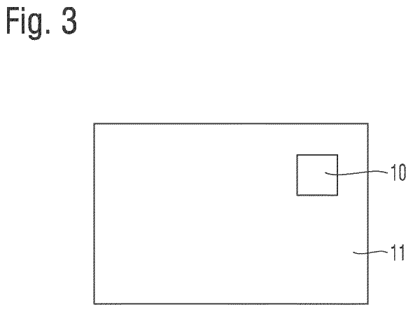

As has been described above, due to the hysteresis of the comparator described, noise may be suppressed. The comparator may be operated at high speed. The comparator may be implemented with low supply voltages so that the energy consumption may be reduced. The comparator may have a small size. Accordingly, the comparator may be used in mobile devices. FIG. 3 shows an example of an electronic device 11 comprising the comparator 10. The electronic device may be implemented as a laser driver, as smart glasses or as a mobile device.

While embodiments of the present disclosure have been described above, it is obvious that further embodiments may be implemented. For example, further embodiments may comprise any subcombination of features recited in the claims or any subcombination of elements described in the examples given above. Accordingly, this spirit and scope of the appended claims should not be limited to the description of the embodiments contained herein.

### LIST OF REFERENCES

10 comparator
11 electronic device
12 current mirror
14 node
16 first transistor
18 second transistor
20 third transistor
22 first inverter
24 second inverter
26 first input transistor
28 second input transistor
30 control inverter
32 control transistor
34 bias transistor
IS input stage
OS output stage
GS gain stage
S1 input signal
S2 input signal
S3 differential current signal
S4 output signal

What is claimed is:

1. A comparator comprising:
an input stage, configured to receive a pair of input signals to generate at least one differential current signal;
an output stage configured to generate an output signal depending on the differential current signal, the output stage comprising a current mirror and a node electrically connected to the current mirror, the current mirror comprising a first transistor, a second and a third transistor, the second and the third transistors being connected in parallel; and
a gain stage comprising a first and a second inverter, wherein an output of the first inverter is input to the second inverter,
wherein an output of the second inverter is configured to control the third transistor to be in a floating or conducting state.

2. The comparator according to claim 1, wherein, if the output of the second inverter is high, the output of the second inverter is configured to control the third transistor to be conductive.

3. The comparator according to claim 1, wherein, if the output of the second inverter is low, the output of the second inverter is configured to control the third transistor to be floating.

4. The comparator according to claim 1, wherein the input stage comprises a first input transistor and a second input transistor, the first input transistor being different from the second input transistor.

5. The comparator according to claim 1, further comprising a control inverter and a control transistor, wherein the output of the second inverter is fed to a gate terminal of the control transistor-via the control inverter.

6. The comparator according to claim 5, wherein the control transistor is implemented as an NMOS transistor.

7. An electronic device comprising a comparator comprising:
an input stage, configured to receive a pair of input signals to generate at least one differential current signal;
an output stage configured to generate an output signal depending on the differential current signal, the output stage comprising a current mirror and a node electrically connected to the current mirror, the current mirror comprising a first transistor, a second and a third transistor, the second and the third transistors being connected in parallel; and
a gain stage comprising a first and a second inverter, wherein an output of the first inverter is input to the second inverter,
wherein an output of the second inverter is configured to control the third transistor to be in a floating or conducting state.

8. The electronic device according to claim 7, being implemented as a laser driver, as smart glasses or as a mobile device.

9. The comparator according to claim 1, wherein the node is electrically connected to the gain stage and configured to receive the at least one differential current signal.
